(19) United States
(12) Patent Application Publication
(10) Pub. No.: US 2025/0015071 A1
(43) Pub. Date: Jan. 9, 2025

(54) ELECTROSTATIC DISCHARGE IN GALLIUM NITRIDE DEVICES

(71) Applicant: Taiwan Semiconductor Manufacturing Company, Ltd., Hsinchu (TW)

(72) Inventors: Sheng-Fu HSU, Hsinchu (TW); Shih-Fan CHEN, Hsinchu City (TW); Lin-Yu HUANG, Hsinchu (TW)

(21) Appl. No.: 18/348,741

(22) Filed: Jul. 7, 2023

(51) Int. Cl. H01L 27/02; H01L 21/8252; H01L 23/522

(52) U.S. Cl. CPC H01L 27/0248; H01L 21/8252; H01L 23/5228

(57) ABSTRACT

Providing a resistor between a gate of a target device (e.g., a gallium nitride (GaN) high-electron-mobility transistor device) and a clamp circuit improves electrostatic discharge (ESD) protection between an input/output (IO) and the target device. For example, the resistor may result in ESD protection between the IO and a source of the target device and between the IO and a drain of the target device may be at least 2 kilovolts under the human body model. Because ESD protection is improved, chances of burn out in the target device are reduced. Additionally, larger currents may be applied in the clamp circuit without risk of ESD.

### BACKGROUND

In transistor structures, such as a complementary metal-oxide-semiconductor (CMOS), and in photonic structures, such as a pixel, higher breakdown voltages allow the transistor to function across a wider range of input signals without breaking. Gallium nitride (GaN) can be used as a material for forming a transistor in order to improve breakdown voltage of the transistor because of the high bandgap exhibited by gallium nitride.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example semiconductor structure described herein.

FIGS. 3A-3D are diagrams of example implementations described herein.

FIG. 4 is a diagram of an example semiconductor structure described herein.

FIG. 5 is a diagram of an example semiconductor structure described herein.

FIG. 6 is a diagram of an example semiconductor structure described herein.

FIGS. 7A-7B are diagrams of example semiconductor structures described herein.

FIGS. 8A-8K are diagrams of an example implementation described herein.

FIG. 9 is a diagram of example components of one or more devices of FIG. 1 described herein.

FIG. 10 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, gallium nitride (GaN) can be used as a material for forming a source, a drain, and/or a channel of a transistor in order to improve breakdown voltage of the transistor because of the high bandgap exhibited by gallium nitride. However, gallium nitride has a very low electrical resistance, which results in greater gate leakage (e.g., current flowing into, or out of, the transistor through the gate) than for other materials.

Electrostatic discharge (ESD) protection in a semiconductor device helps prevent short-circuits that render the device non-functional. However, in a GaN device, ESD protection between an input/output (IO) and the semiconductor device may be smaller than ESD protection within the device (e.g., between a source and a drain of the semiconductor device). Indeed, ESD protection between the IO and a source of the semiconductor device and between the IO and a drain of the semiconductor device may be less than 1 kilovolt (kv) under the human body model (HBM). As a result, larger voltages and/or larger voltage changes can cause excessive current to flow through a gate of the semiconductor device and damage the gate.

Some implementations described herein provide techniques and apparatuses for providing a resistor between a gate of a target device, such as a gallium nitride (GaN) transistor, and a clamp circuit. As a result, ESD protection between an IO and the device is improved. For example, the resistor may result in ESD protection between the IO and a source of the target device and between the IO and a drain of the target device may be at least 2 kv under the HBM. Because ESD protection is improved, chances of burn out in the target device are reduced. Additionally, larger currents may be applied in the clamp circuit without risk of ESD.

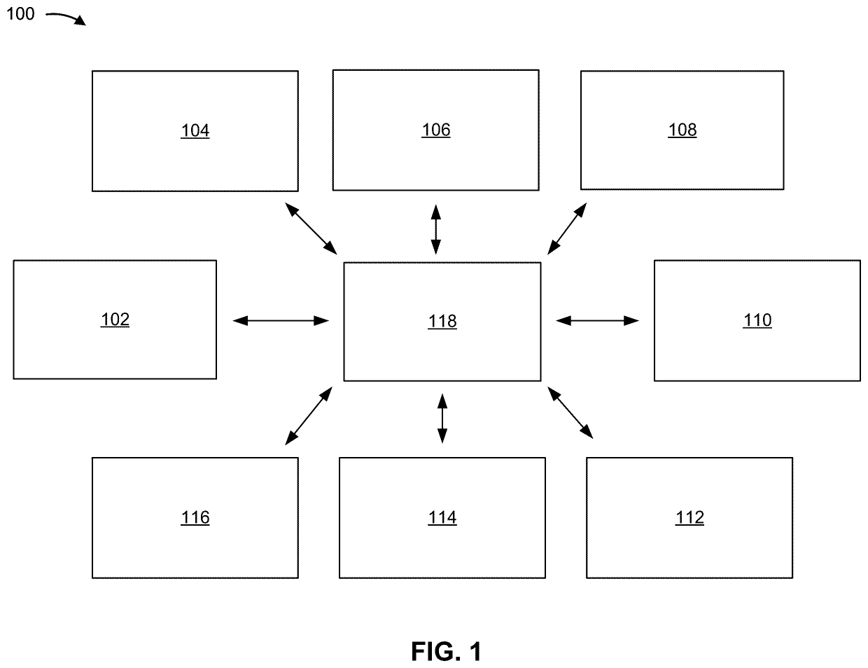

FIG. 1 is a diagram of an example environment 100 in which systems and/or methods described herein may be implemented. As shown in FIG. 1, environment 100 may include a plurality of semiconductor processing tools 102-116 and a wafer/die transport tool 118. The plurality of semiconductor processing tools 102-116 may include a deposition tool 102, an exposure tool 104, a developer tool 106, an etch tool 108, a planarization tool 110, a plating tool 112, a photoresist removal tool 114, an annealing tool 116, and/or another semiconductor processing tool. The tools included in the example environment 100 may be included in a semiconductor clean room, a semiconductor foundry, a semiconductor processing and/or manufacturing facility, or another location.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, an epitaxy tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The photoresist removal tool 114 is a semiconductor processing tool that is capable of removing remaining portions of a photoresist layer from a substrate after the etch tool 108 removes portions of the substrate. For example, the photoresist removal tool 114 may use a chemical stripper and/or another technique to remove a photoresist layer from a substrate.

The annealing tool 116 is a semiconductor processing tool that includes a semiconductor processing chamber and one or more devices capable of heating a semiconductor substrate or semiconductor device. For example, the annealing tool 116 may include a rapid thermal annealing (RTA) tool or another type of annealing tool that is capable of heating a semiconductor substrate to cause a reaction between two or more materials or gasses, to cause a material to decompose. As another example, the annealing tool 116 may be configured to heat (e.g., raise or elevate the temperature of) a structure or a layer (or portions thereof) to re-flow the structure or the layer, or to crystallize the structure or the layer, to remove defects such as voids or seams. As another example, the annealing tool 116 may be configured to heat (e.g., raise or elevate the temperature of) a layer (or portions thereof) to enable bonding of two or more semiconductor devices.

The wafer/die transport tool 118 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 118 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

In some implementations, one or more of the semiconductor processing tools 102-116 and/or the wafer/die transport tool 118 may perform one or more semiconductor processing operations described herein. For example, one or more of the semiconductor processing tools 102-116 and/or the wafer/die transport tool 118 may form a contact over a source of a GaN transistor, form a resistor that contacts a gate of the GaN transistor, and/or form a clamp circuit connected to the contact and the resistor, among other examples.

The number and arrangement of tools shown in FIG. 1 are provided as one or more examples. In practice, there may be additional tools, fewer tools, different tools, or differently arranged tools than those shown in FIG. 1. Furthermore, two or more tools shown in FIG. 1 may be implemented within a single tool, or a single tool shown in FIG. 1 may be implemented as multiple, distributed tools. Additionally, or alternatively, a set of tools (e.g., one or more tools) of environment 100 may perform one or more functions described as being performed by another set of tools of environment 100.

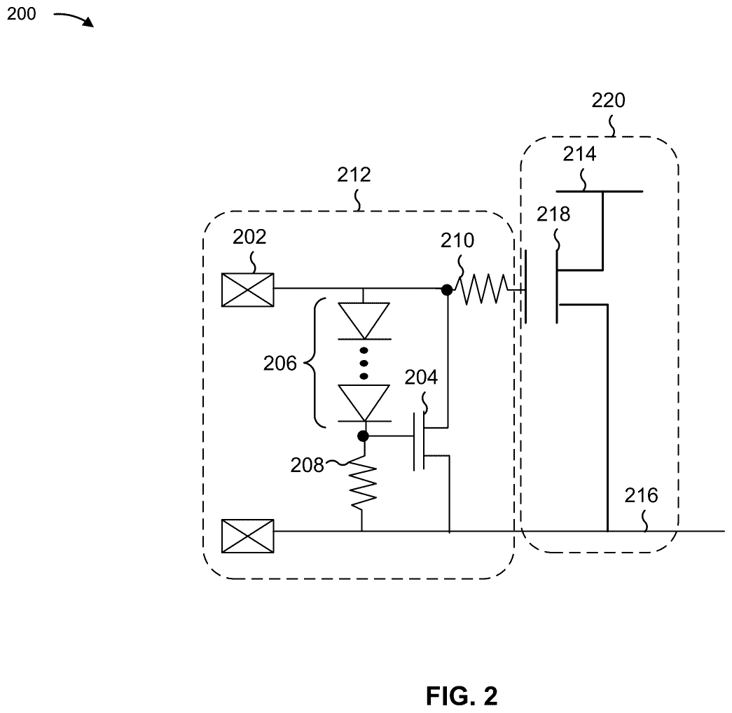

FIG. 2 is a diagram of an example semiconductor structure 200 described herein. The example semiconductor structure 200 includes a resistor over a gate in order to improve ESD protection. In some implementations, the example semiconductor structure 200 illustrated in FIG. 2 may be included in a processor, a memory, or another type of electronic device.

As shown in FIG. 2, a control device 202 may be connected to an IO for the example semiconductor structure 200. The control device 202 may be a device that supplies a voltage to operate the semiconductor structure 200 (e.g., by varying the voltage to turn the semiconductor structure 200 on and off, among other examples).

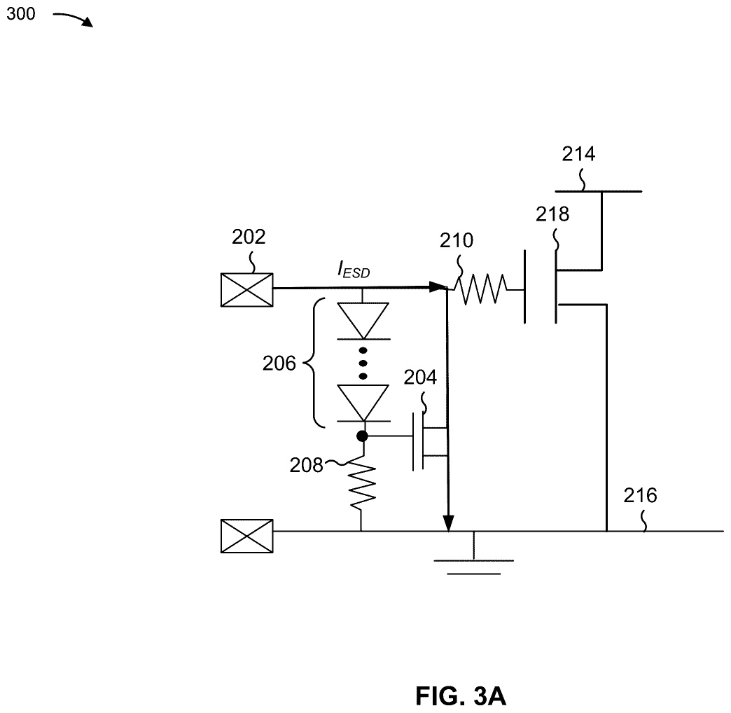

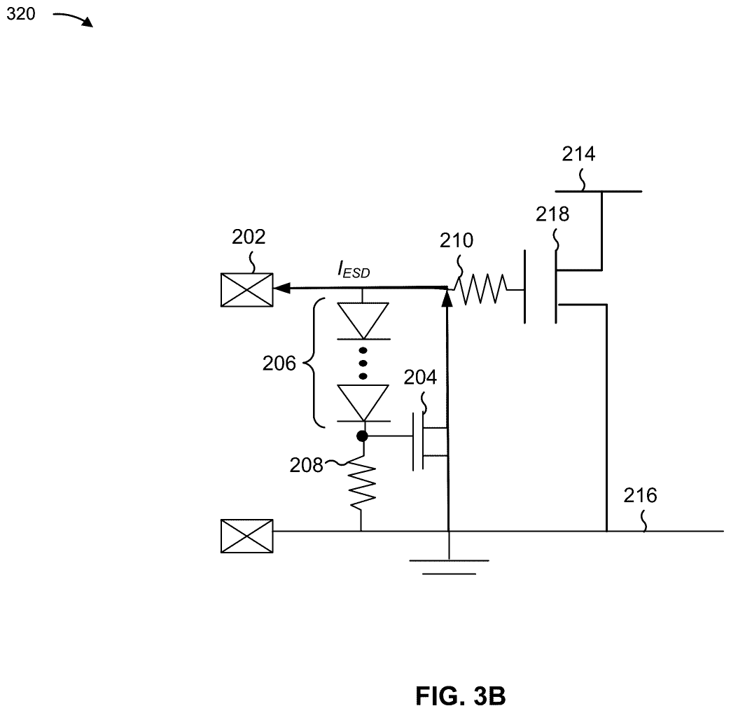

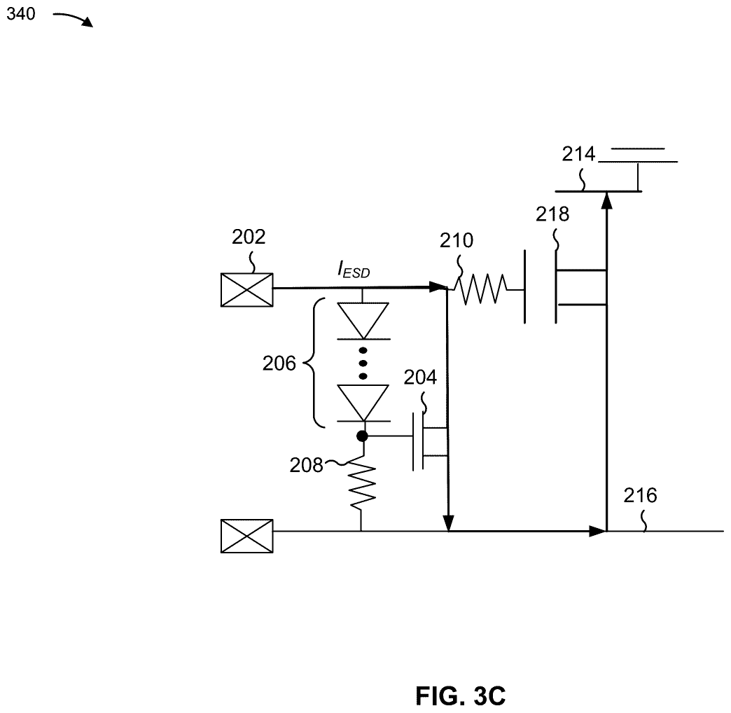

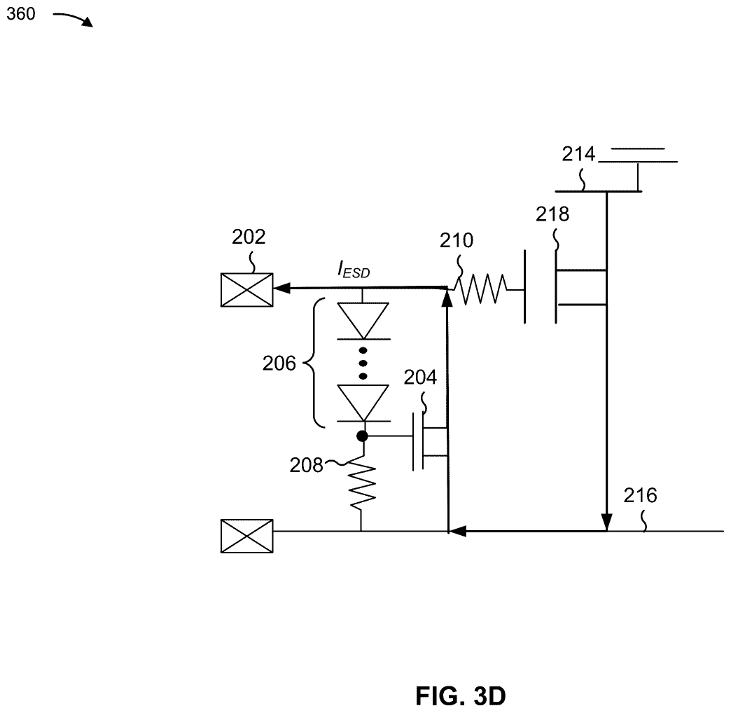

In order to provide for ESD of excessive voltage (and/or current), the example semiconductor structure 200 may include a field-effect transistor (FET) 204 configured to activate an ESD process (e.g., as described in connection with FIGS. 3A-3D). The FET 204 may be silicon-based (e.g., an n-channel metal-oxide semiconductor (NMOS) or a p-channel metal-oxide semiconductor (PMOS)) or may be GaN-based (e.g., an n-type high-electron-mobility transistor (HEMT)). Silicon-based FETs are faster to manufacture while GaN-based FETs operate under higher voltage thresholds. In order to increase a voltage threshold of the silicon-based FET, the FET 204 may be a buried inverted gate FET (BigFET), which is generally larger than other NMOS and PMOS transistors.

As further shown in FIG. 2, the FET 204 may be controlled by a series of diodes 206. Because a voltage drop across the series of diodes 206 is constant, the FET 204 will activate only when a voltage from the control device 202 satisfies a voltage threshold determined by properties of the series of diodes 206 (e.g., a cut-off voltage that is based on a voltage drop per diode and a quantity of the diodes). Depending on the voltage threshold desired, the series of diodes 206 may include different quantities of diodes, such as between three and eight. However, other quantities of diodes are within the scope of the present disclosure. The series of diodes 206 may be silicon-based (e.g., metal-oxide semiconductor (MOS) diodes) or may be GaN-based (e.g., HEMT diodes). Silicon-based diodes are faster to manufacture while GaN-based diodes operate under higher voltage thresholds.

A resistor 208 may protect the series of diodes 206 from excessive current. The resistor 208 may include a silicon resistor (e.g., a silicon chromium (SiCr) resistor, an oxide definition (OD) resistor, a power oxide (PO) resistor, or a metal gate resistor, among other examples), a metal nitride resistor (e.g., a titanium nitride (TiN) resistor), or a GaN resistor (e.g., a two-dimensional electron gas (2 DEG) resistor).

Additionally, a resistor 210 may be in parallel with the FET 204. As shown in FIG. 2, a drain 214, a source 216, and a gate 218 may form a target device 220 that is controlled by the control device 202. Therefore, the resistor 210 electrically (and physically) connects the clamp circuit 212 to the gate 218 of the target device. The resistor 210 may include a silicon resistor (e.g., an SiCr resistor, an OD resistor, a PO resistor, or a metal gate resistor, among other examples), a metal nitride resistor (e.g., a TiN resistor), or a GaN resistor (e.g., a 2 DEG resistor). The gate 218 may be a GaN gate. As used herein, a “GaN gate” may refer to a gate formed of gallium nitride and/or a gate of a GaN HEMT device, such as a gate formed over crystallized GaN, where the crystallized GaN functions as a channel for the GaN HEMT device.

The source 216 of the target device 220 may also be connected to the clamp circuit 212 (e.g., in parallel with the FET 204). Therefore, the clamp circuit 212 may perform an ESD using the source 216 (e.g., as described in connection with FIGS. 3A and 3B) or using a channel of the target device 220 from the source 216 to the drain 214 (e.g., as described in connection with FIGS. 3C and 3D).

The resistor 210 protects the gate 218 during the ESD (e.g., as described in connection with FIGS. 3A-3C). This protection is particularly important when the target device 220 is a GaN transistor, such that the ESD protection between the IO and the source 216 and between the IO and the drain 214 is at least 2 kv under the HBM. Without at least 2 kv of ESD protection, the gate 218 is likely to burn out during ESD. Additionally, when the target device 220 is a GaN transistor, the resistor 210 opens a channel of the target device 220 during an ESD from the drain 214 to the gate 218 (e.g., as described in connection with FIG. 3D), which prevents the ESD from burning out the gate 218 due to gate leakage.

As indicated above, FIG. 2 is provided as an example. Other examples may differ from what is described with regard to FIG. 2.

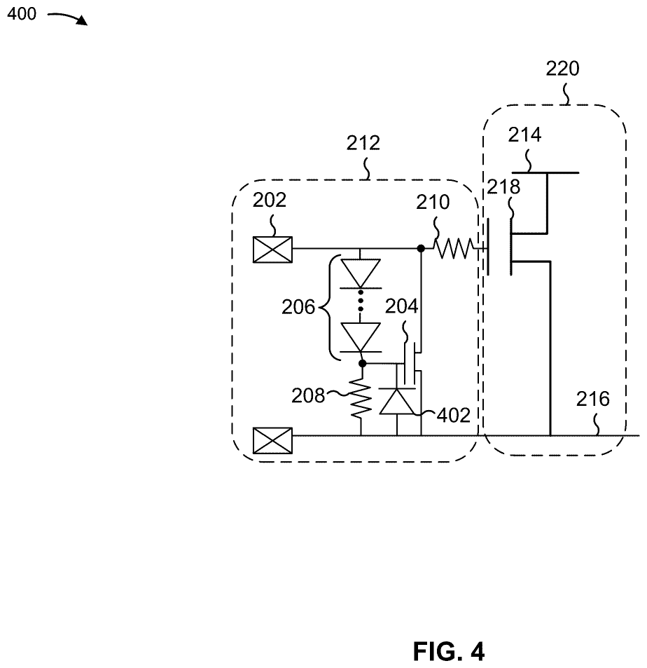

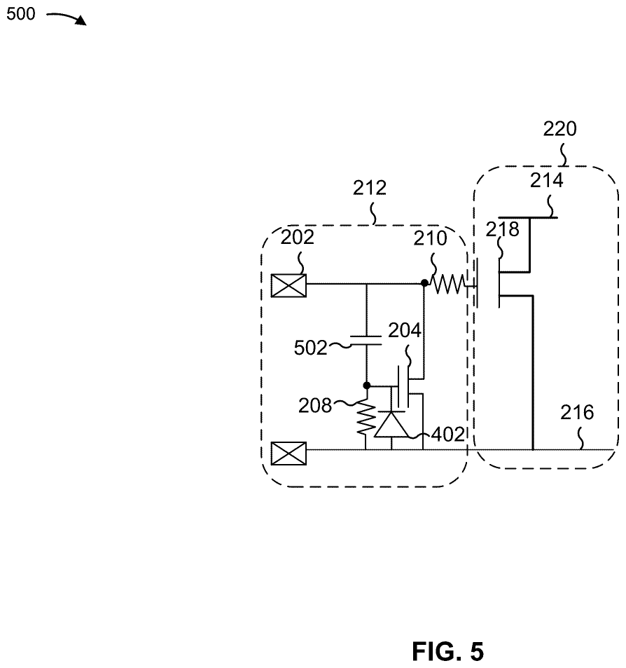

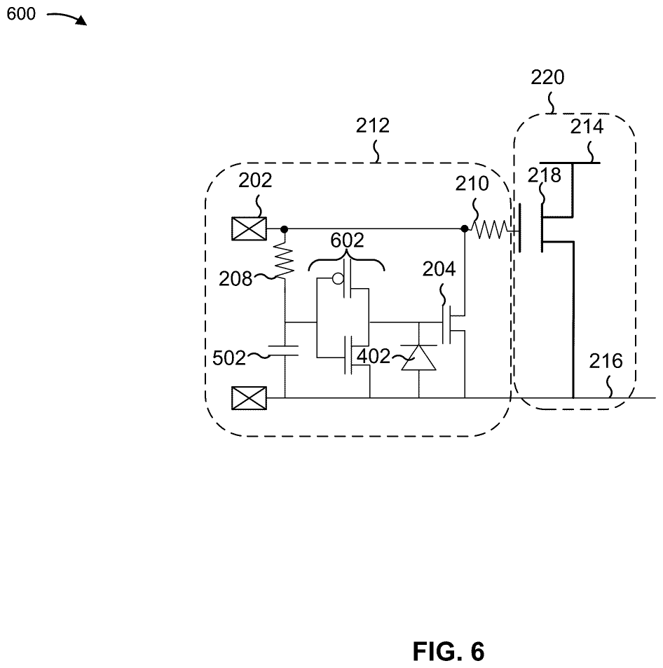

FIG. 3A is a diagram of an example implementation 300 described herein. Example implementation 300 may be an example process for performing an ESD in the example semiconductor structure 200 described in connection with FIG. 2. In some implementations, the example techniques and procedures described in connection with FIG. 3A may be used in connection with other semiconductor structures described herein, such as the example semiconductor structure 400 described in connection with FIG. 4, the example semiconductor structure 500 described in connection with FIG. 5, or the example semiconductor structure 600 described in connection with FIG. 6. The example process shown using example implementation 300 may be performed in a processor, a memory, or another type of electronic device.

As shown in FIG. 3A, a positive voltage at the IO of the clamp circuit that exceeds a cut-off voltage of the series of diodes 206 results in an ESD (shown by a current represented by I_{ESD} in FIG. 3A). Because the voltage at the IO exceeds the cut-off voltage, the FET 204 is activated to allow the ESD from the IO to the source 216, which functions as a ground, as shown in FIG. 3A. During the ESD, the resistor 210 protects the gate 218 from the current represented by I_{ESD}. In particular, the current represented by I_{ESD} will flow across the FET 204 rather than across the gate 218 because the resistor 210 has a non-negligible resistance.

FIG. 3B is a diagram of an example implementation 320 described herein. Example implementation 320 may be an example process for performing an ESD in the example semiconductor structure 200 described in connection with FIG. 2. In some implementations, the example techniques and procedures described in connection with FIG. 3B may be used in connection with other semiconductor structures described herein, such as the example semiconductor structure 400 described in connection with FIG. 4, the example semiconductor structure 500 described in connection with FIG. 5, or the example semiconductor structure 600 described in connection with FIG. 6. The example process shown using example implementation 320 may be performed in a processor, a memory, or another type of electronic device.

As shown in FIG. 3B, a negative voltage at the IO of the clamp circuit results in an ESD (shown by a current represented by I_{ESD} in FIG. 3B). In particular, the FET 204 is activated to allow the ESD from the source 216 to the IO, as shown in FIG. 3B. During the ESD, the resistor 210 protects the gate 218 from the current represented by I_{ESD}. In particular, the current represented by I_{ESD} will flow across the FET 204 rather than across the gate 218 because the resistor 210 has a non-negligible resistance.

FIG. 3C is a diagram of an example implementation 340 described herein. Example implementation 340 may be an example process for performing an ESD in the example semiconductor structure 200 described in connection with FIG. 2. In some implementations, the example techniques and procedures described in connection with FIG. 3C may be used in connection with other semiconductor structures described herein, such as the example semiconductor structure 400 described in connection with FIG. 4, the example semiconductor structure 500 described in connection with FIG. 5, or the example semiconductor structure 600 described in connection with FIG. 6. The example process shown using example implementation 340 may be performed in a processor, a memory, or another type of electronic device.

As shown in FIG. 3C, positive voltage at the IO of the clamp circuit that exceeds a cut-off voltage of the series of diodes 206 results in an ESD (shown by a current represented by I_{ESD} in FIG. 3C). Because the voltage at the IO exceeds the cut-off voltage, the FET 204 is activated to allow the ESD from the IO to the drain 214, which functions as a ground, as shown in FIG. 3C. During the ESD, the resistor 210 protects the gate 218 from the current represented by I_{ESD}. In particular, the current represented by I_{ESD} will flow across the FET 204 rather than across the gate 218 because the resistor 210 has a non-negligible resistance.

FIG. 3D is a diagram of an example implementation 360 described herein. Example implementation 360 may be an example process for performing an ESD in the example semiconductor structure 200 described in connection with FIG. 2. In some implementations, the example techniques and procedures described in connection with FIG. 3D may be used in connection with other semiconductor structures described herein, such as the example semiconductor structure 400 described in connection with FIG. 4, the example semiconductor structure 500 described in connection with FIG. 5, or the example semiconductor structure 600 described in connection with FIG. 6. The example process shown using example implementation 360 may be performed in a processor, a memory, or another type of electronic device.

As shown in FIG. 3D, a negative voltage at the IO of the clamp circuit results in an ESD (shown by a current represented by I_{ESD} in FIG. 3D). In particular, the FET 204 is activated to allow the ESD from the drain 214 to the IO, as shown in FIG. 3D. During the ESD, leakage current through the gate 218 results in a non-zero voltage drop across the resistor 210, which then activates the gate 218 and opens the channel of the target device. Without the resistor 210, the ESD would flow through the gate 218 without causing a non-zero voltage drop, and the ESD would thus burn out the gate 218. As a result of the non-zero voltage drop across the resistor 210, the current represented by I_{ESD} will flow across the channel rather than through the gate 218.

As indicated above, FIGS. 3A-3D are provided as examples. Other examples may differ from what is described with regard to FIGS. 3A-3D.

FIG. 4 is a diagram of an example semiconductor structure 400 described herein. The example semiconductor structure 400 is similar to the example semiconductor structure 200, except that a forward diode 402 is included in parallel with the resistor 208 that controls the FET 204. As a result, an ESD caused by a negative voltage at the IO (e.g., as described in connection with FIGS. 3B and 3D) is triggered based on the negative voltage satisfying a voltage threshold determined by properties of the forward diode 402 (e.g., a cut-off voltage of the forward diode 402). Therefore, the forward diode 402 triggers an ESD, caused by the negative voltage, faster than if the forward diode 402 were omitted. The forward diode 402 may be silicon-based (e.g., an MOS diode) or may be GaN-based (e.g., an HEMT diode). Silicon-based diodes are faster to manufacture while GaN-based diodes operate under higher voltage thresholds.

FIG. 5 is a diagram of an example semiconductor structure 500 described herein. The example semiconductor structure 500 is similar to the example semiconductor structure 400, except that a capacitor 502 is used in lieu of the series of diodes 206 to control the FET 204. The capacitor 502 may include a metal-insulator-metal (MIM) capacitor, a metal-oxide-metal (MOM) capacitor, or a GaN-based capacitor (e.g., an HEMT capacitor).

In the example semiconductor structure 500, the capacitor 502 and the resistor 208 form an RC circuit with a time constant. As a result, ESD is triggered when a rising time associated with the voltage at the IO exceeds the time constant. In other words, in FIG. 5, the clamp circuit 212 is configured to perform ESD based on a time constant instead of, as in FIG. 2 and FIG. 4, a voltage threshold. The clamp circuit 212 shown in FIG. 5 may also be referred to as a “capacitor-resistor clamp” because the clamp circuit 212 includes the capacitor 502, followed by the resistor 208, after the IO.

FIG. 6 is a diagram of an example semiconductor structure 600 described herein. The example semiconductor structure 600 is similar to the example semiconductor structure 500, except that an inverter 602 is coupled with the resistor 208 and the capacitor 502 to control the FET 204. The inverter 602 may be a stage 1 inverter, a stage 3 inverter, a stage 5 inverter, a stage 7 inverter, a stage 9 inverter, or a stage 11 inverter, among other examples. Additional stages increase manufacturing time and raw materials consumed but also reduce a delay between an increase (or decrease) of voltage at the IO and trigger of an ESD.

In the example semiconductor structure 500, the capacitor 502 and the resistor 208 form an RC circuit with a time constant. As a result, ESD is triggered when a rising time associated with the voltage at the IO exceeds the time constant. In other words, in FIG. 6, the clamp circuit 212 is configured to perform ESD based on a time constant instead of, as in FIG. 2 and FIG. 4, a voltage threshold. The clamp circuit 212 shown in FIG. 6 may also be referred to as a “resistor-capacitor clamp” because the clamp circuit 212 includes the resistor 208, followed by the capacitor 502, after the IO.

Additionally, the inverter 602 helps trigger the ESD by amplifying voltage at the FET 204 when the time constant is exceeded. Accordingly, the clamp circuit 212 shown in FIG. 6 may also be referred to as a “resistor-capacitor-inverter clamp.”

As indicated above, FIGS. 4-6 are provided as examples. Other examples may differ from what is described with regard to FIGS. 4-6. For example, the forward diode 402 may be omitted from the example semiconductor structure 400 of FIG. 4, the example semiconductor structure 500 of FIG. 5, or the example semiconductor structure 600 of FIG. 6.

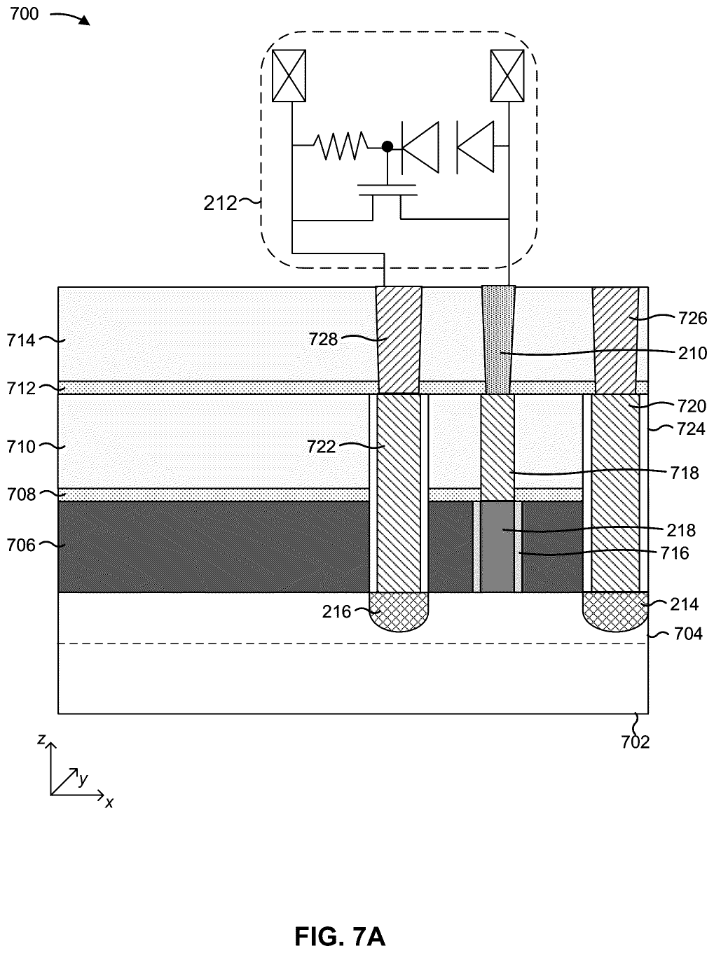

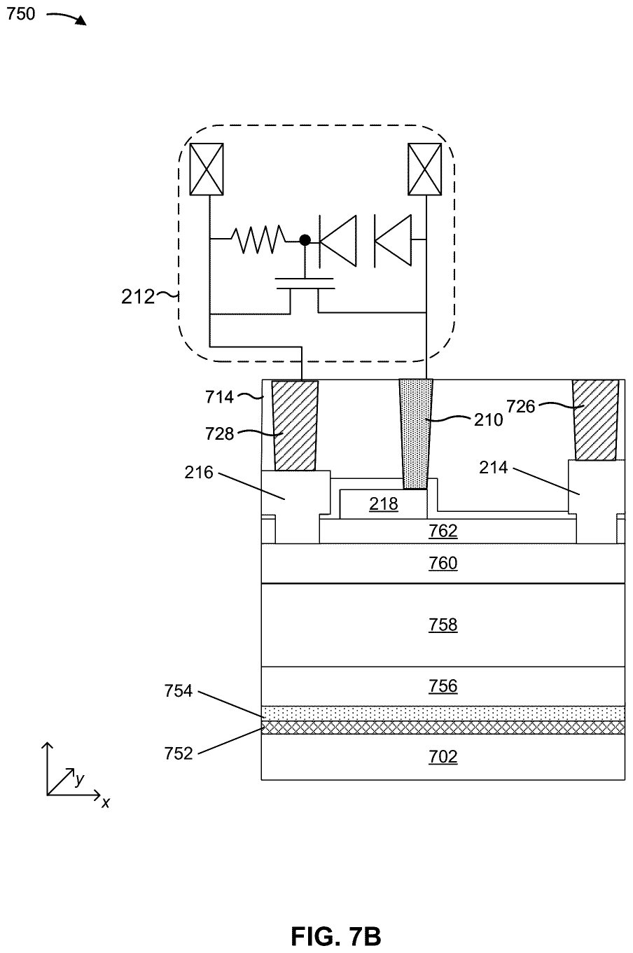

FIG. 7A is a diagram of a portion of an example semiconductor structure 700 described herein. The example semiconductor structure 700 may be included in a memory device, a logic device, a processor, an input/output device, or another type of semiconductor device that includes one or more transistors.

The example semiconductor structure 700 includes one or more stacked layers. As shown in FIG. 7A, the example semiconductor structure 700 includes a substrate 702. The substrate 702 may include a semiconductor die substrate, a semiconductor wafer, or another type of substrate in which semiconductor pixels may be formed. In some implementations, the substrate 702 is formed of silicon (Si), a material including silicon, a III-V compound semiconductor material such as gallium arsenide (GaAs), a silicon on insulator (SOI), or another type of semiconductor material that is capable of generating a charge from photons of incident light. In some implementations, the substrate 702 is formed of a doped material (e.g., a p-doped material or an n-doped material) such as a doped silicon.

The example semiconductor structure 700 further includes a plurality of epitaxial (epi) regions that are grown and/or otherwise formed on and/or around portions of a fin structure 704 of the substrate 702. The epitaxial regions are formed by epitaxial growth. In some implementations, the epitaxial regions are formed in recessed portions in the fin structure 704. The recessed portions may be formed by strained source drain (SSD) etching of the fin structure 704 and/or another type etching operation. The epitaxial regions function as a drain 214 and a source 216 of a transistor included in the example semiconductor structure 700.

As further shown in FIG. 7A, the example semiconductor structure 700 includes a dielectric layer 706, an etch stop layer (ESL) 708, a dielectric layer 710, an ESL 712, and a dielectric layer 714, among other examples. The dielectric layers 706, 710, and 714 are included to electrically isolate various structures of the example semiconductor structure 700. The dielectric layers 706, 710, and 714 may each include a silicon nitride (SiNₓ), an oxide (e.g., a silicon oxide (SiOₓ) and/or another oxide material), and/or another type of dielectric material. The ESLs 708 and 712 may each include a layer of material that is configured to permit various portions of the example semiconductor structure 700 (or the layers included therein) to be selectively etched or protected from etching to form one or more of the structures included in the example semiconductor structure 700.

The transistor further includes a gate 218 (sometimes referred to as an “MG,” even when formed of crystalline material), which is formed of a polysilicon material, a metal (e.g., tungsten (W) or another metal), and/or another type of conductive material. In some implementations, the gate 218 of the transistor may include multiple layers of material, such as multiple layers of metal or multiple layers including at least one polysilicon layer and at least one metal layer, among other examples. The gate 218 may be isolated by a spacer 716 on each side of the gate 218. The spacer 716 may include a silicon oxide (SiOₓ), a silicon nitride (Si_{X}N_{y}), a silicon oxy carbide (SiOC), a silicon oxycarbonitride (SiOCN), and/or another suitable material. The gate 218 is further connected to a gate contact 718 (also referred to as a “gate via” or “VG”). The gate contact 718 may include tungsten (W), cobalt (Co), ruthenium (Ru), titanium (Ti), aluminum (Al), copper (Cu), or gold (Au), among other examples of conductive materials.

The drain 214 is electrically connected to a drain contact 720. The drain contact 720 (also referred to as an “MD”) may include cobalt (Co), ruthenium (Ru), tungsten (W), and/or another conductive or metal material. In some implementations, the drain contact 720 may be isolated by a spacer 724 on each side of the drain contact 720. The spacer 724 may include a silicon oxide (SiOₓ), a silicon nitride (SiₓN_{y}), a silicon oxy carbide (SiOC), a silicon oxycarbonitride (SiOCN), and/or another suitable material. Similarly, the source 216 is electrically connected to a source contact 722. The source contact 722 (sometimes referred to as an “MD,” even though connected to the source 216 rather than the drain 214) may include cobalt (Co), ruthenium (Ru), tungsten (W), and/or another conductive or metal material. In some implementations, the source contact 722 may be isolated by a spacer 724 on each side of the source contact 722. Alternatively, the spacer 724 may be omitted from sidewalls of the drain contact 720 and/or the source contact 722.

As further shown in FIG. 7A, a resistor 210 is formed over the gate contact 718. The resistor 210 protects the gate 218 during ESD, as described in connection with FIGS. 3A-3D. Although the example semiconductor structure 700 includes the resistor 210 in a middle end of line (MEOL), other examples may include additional metallization layers between the gate 218 and the resistor 210, such that the resistor 210 is included in a back end of line (BEOL). As described in connection with FIG. 2, the resistor 210 may include a silicon resistor (e.g., an SiCr resistor, an OD resistor, a PO resistor, or a metal gate resistor, among other examples), a metal nitride resistor (e.g., a TiN resistor), or a GaN resistor (e.g., a 2 DEG resistor).

A contact 726 may electrically connect the drain 214 to a ground or another destination. Additionally, a contact 728 may electrically connect the source 216 to a clamp circuit 212 (e.g., as described in connection with FIGS. 4-6). Accordingly, the clamp circuit 212 may be included in a BEOL. In some implementations, the example semiconductor structure 700 further includes BEOL layers that connect the example semiconductor structure 700 to a package. Accordingly, the clamp circuit 212 may be formed over additional BEOL layers.

FIG. 7B is a diagram of a portion of an example semiconductor structure 750 described herein. The example semiconductor structure 750 may be included in a memory device, a logic device, a processor, an input/output device, or another type of semiconductor device that includes one or more transistors.

The example semiconductor structure 750 includes one or more stacked layers. As shown in FIG. 7B, the example semiconductor structure 750 includes a substrate 702. The substrate 702 may be as described in connection with FIG. 7A.

As further shown in FIG. 7B, an adhesive layer 752 (e.g., formed of an oxide, such as silicon oxide) may attach a growth seed layer 754 to the substrate 702. The growth seed layer 754 may allow for growth of crystalline gallium nitride for a channel of the example semiconductor structure 750.

The example semiconductor structure 750 may further include a seed layer 756. For example, the growth seed layer 754 may chemically bind to a precursor such that the seed layer 756 may be formed by epitaxial growth.

In some implementations, the seed layer 756 also functions as a buffer layer. Although FIG. 7B depicts the seed layer 756 as a single layer, other examples may include multiple seed layers that are arranged to improve lattice matching, reduce threading dislocations, reduce tensile stress, and/or improve a quality of the drain 214, the source 216, and the gate 218.

As further shown in FIG. 7B, the example semiconductor structure 750 may include a gallium nitride buffer layer 758. The buffer layer 758 provides improve lattice matching between a remaining portion of the example semiconductor structure 750 and the seed layer 756 (as well as the substrate 702).

Some examples may include one or more additional buffer layers (e.g., formed between the buffer layer 758 and the seed layer 756). For example, an additional buffer layer may provide additional lattice matching between the buffer layer 758 and the seed layer 756. In some embodiments, an additional buffer layer of a group III-V material that has varying concentrations for group III and group V elements as a function of depth may be included.

A layer 760 of undoped gallium nitride may provide a channel for the example semiconductor structure 750. The layer 760 of undoped gallium nitride may be formed over the buffer layer 758 such that the effects of lattice mismatch between the gallium nitride of the layer 758 and the seed layer 756 are reduced. In some implementations, the layer 760 may be unintentionally doped gallium nitride (also referred to as “UID-GaN”). For example, the layer 760 may, rather than having intentionally placed dopants, have a doping resulting from process contaminants. In some implementations, the layer 760 has an n-type doping.

A layer 762 of aluminum gallium nitride may be formed over the layer 760 of undoped gallium nitride. Because the layer 762 has a different bandgap than the layer 760, the layers 760 and 762 may form a heterojunction structure for the example semiconductor structure 750. For example, the layer 760 may function as a III-V channel layer with a first bandgap, and the layer 762 may function as a barrier layer with a second bandgap that is different from the first bandgap. Although FIG. 7B depicts the layer 760 as a single layer, other examples may include a stacked barrier layer.

As further shown in FIG. 7B, the source 216 and the drain 214 are disposed over an upper surface of the heterojunction structure. Additionally, the gate 218 may be formed over the heterojunction structure between the source 216 and the drain 214.

As further shown in FIG. 7B, and similarly as in FIG. 7A, the resistor 210 is formed over the gate 218. Additionally, the contact 726 may electrically connect the drain 214 to a ground or another destination, and the contact 728 may electrically connect the source 216 to the clamp circuit 212 (e.g., as described in connection with FIGS. 4-6). In some implementations, the example semiconductor structure 750 further includes BEOL layers that connect the example semiconductor structure 750 to a package. Accordingly, the clamp circuit 212 may be formed over additional BEOL layers.

As indicated above, FIGS. 7A and 7B are provided as examples. Other examples may differ from what is described with regard to FIGS. 7A and 7B. For example, other implementations may include the resistor 210 (and/or the clamp circuit 212) on a separate substrate. As a result, the resistor 210 (and/or the clamp circuit 212) may be connected to the example semiconductor structure 700 or the example semiconductor structure 750 via wafer bonding rather than by being formed on the same substrate 702.

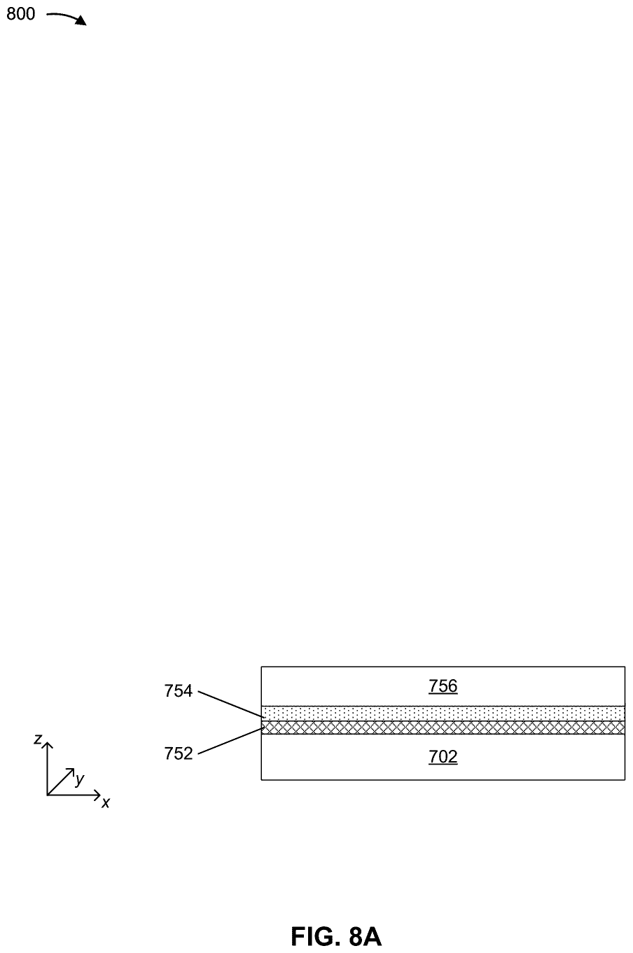

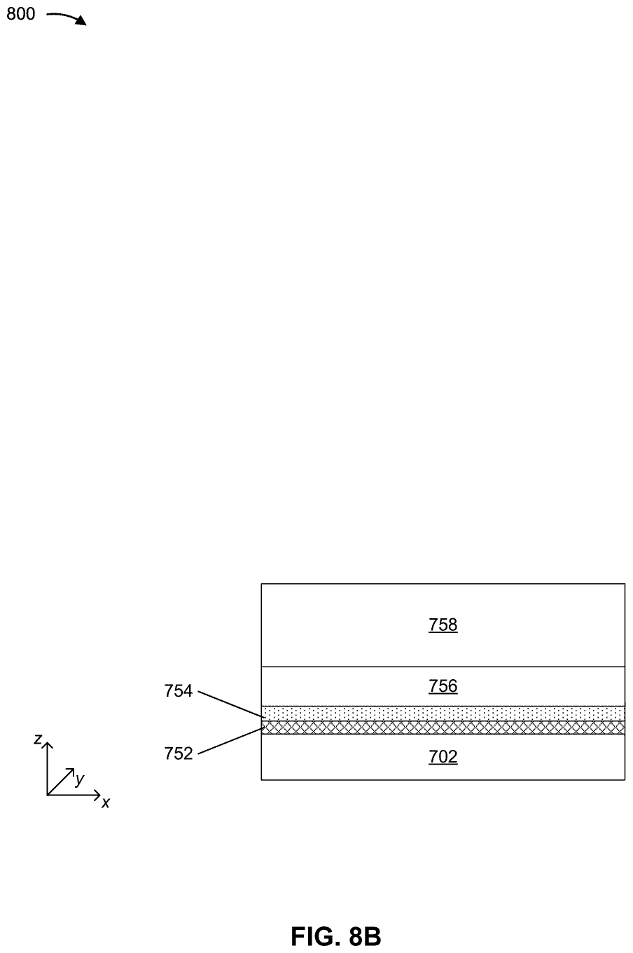

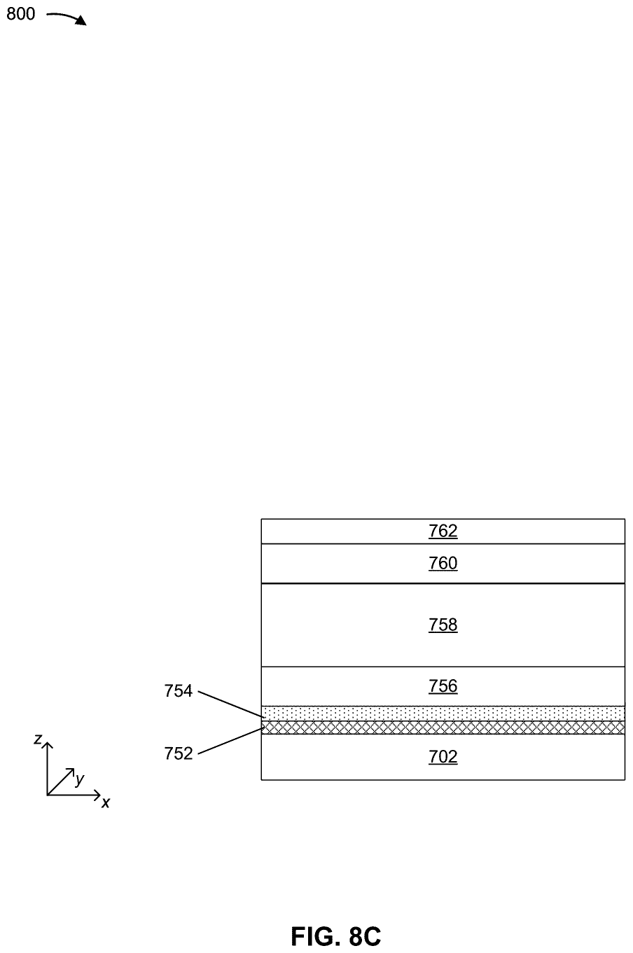

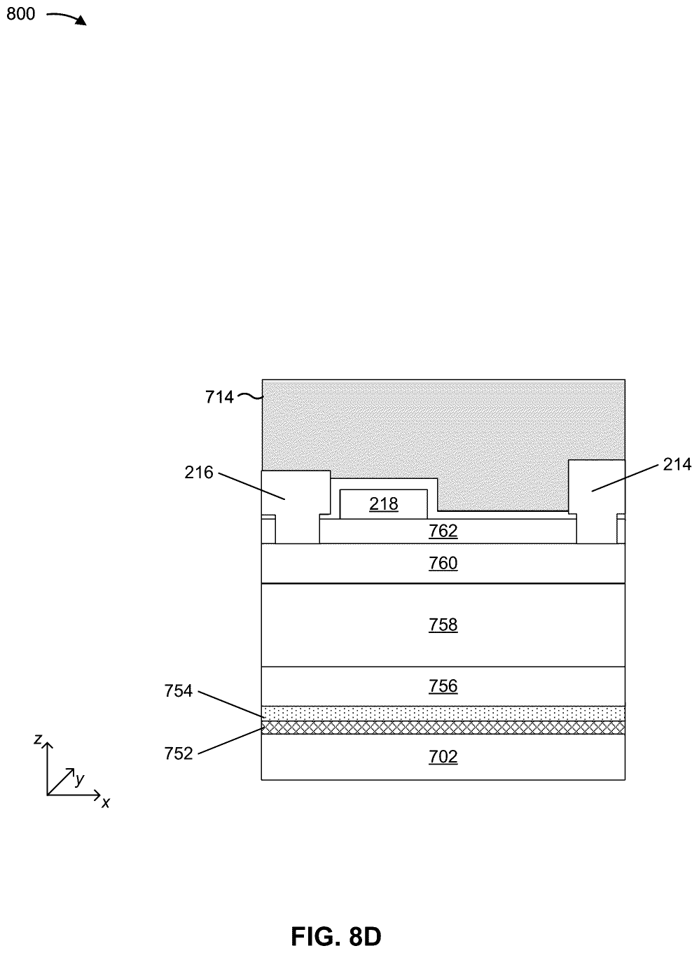

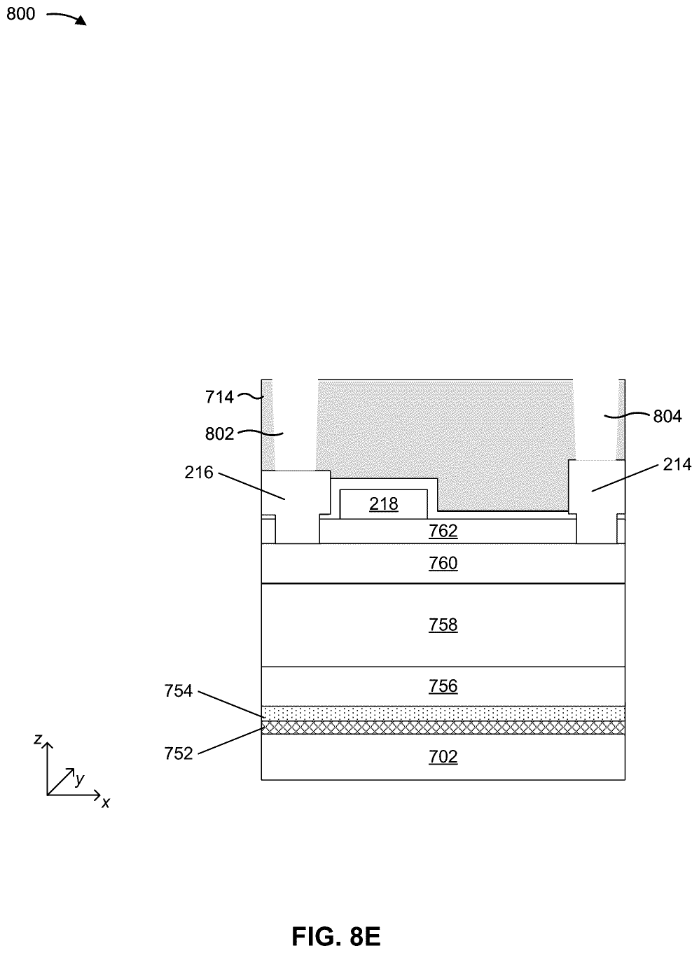

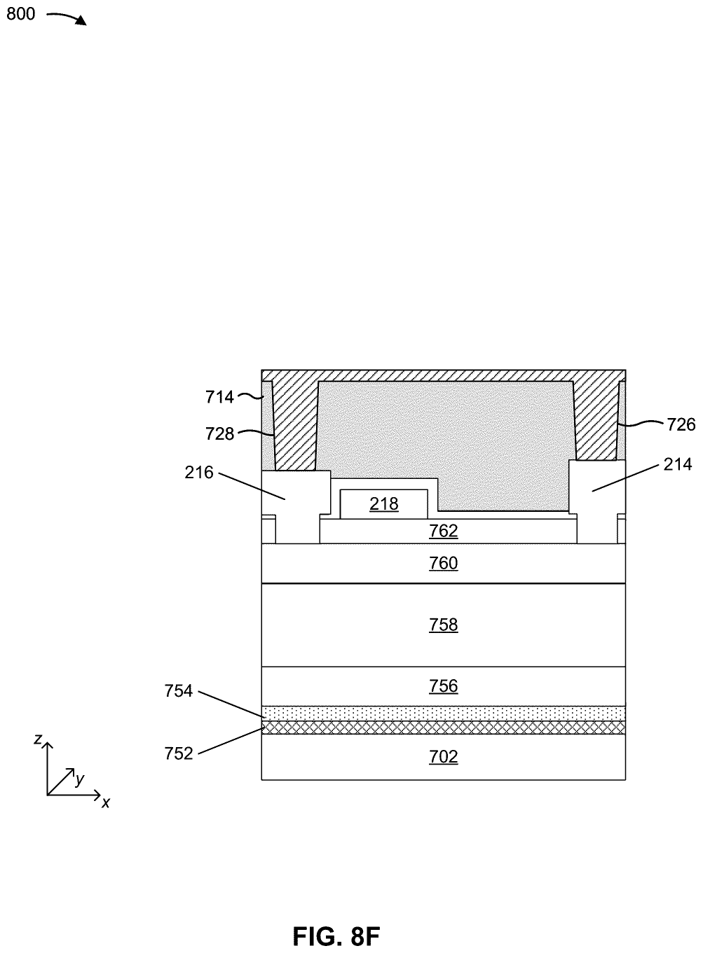

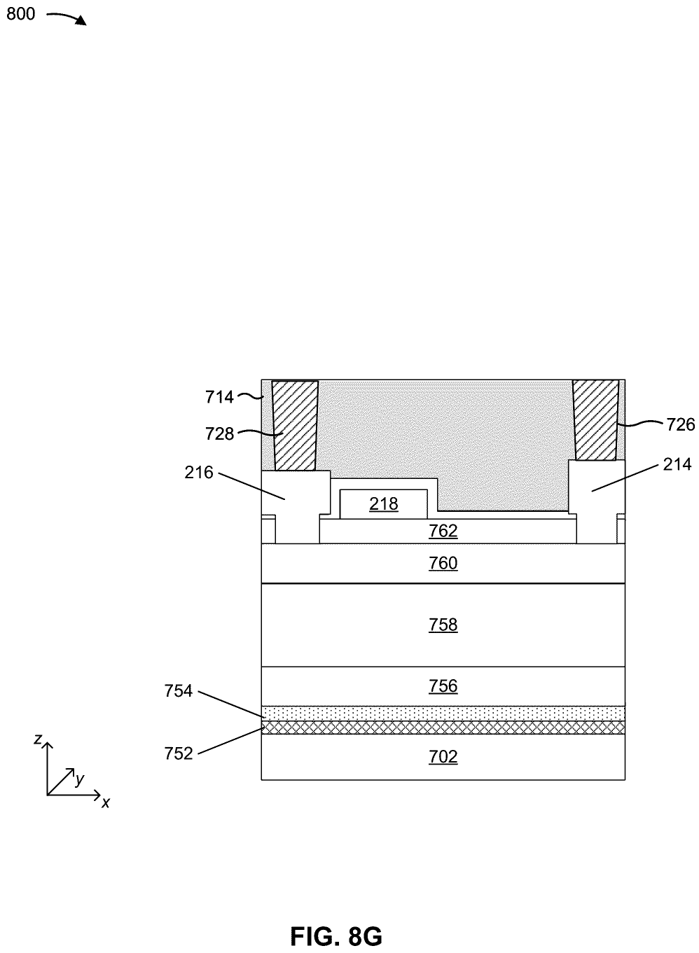

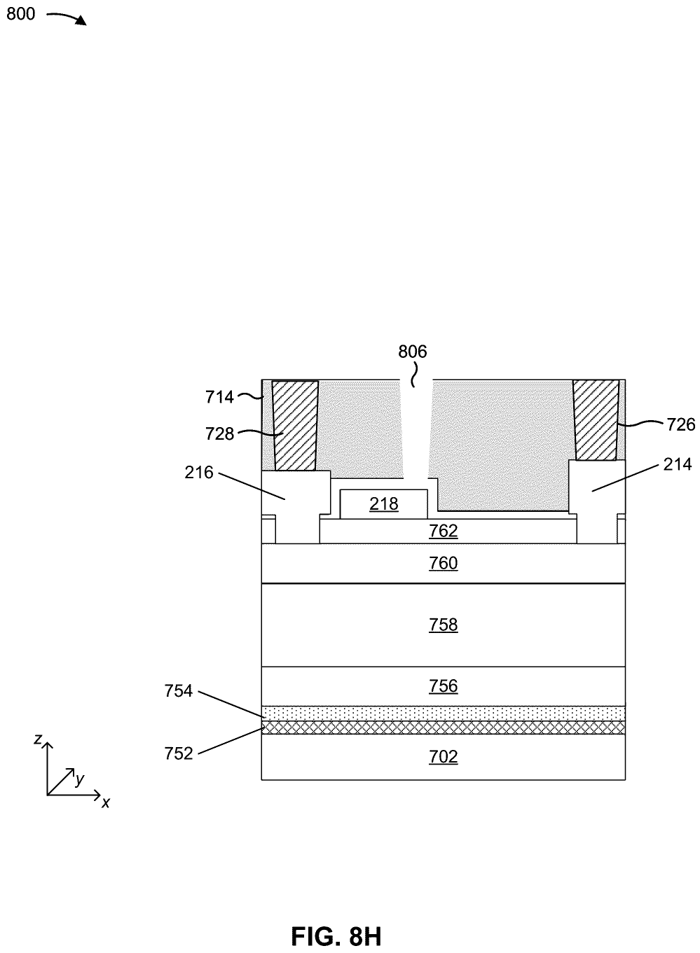

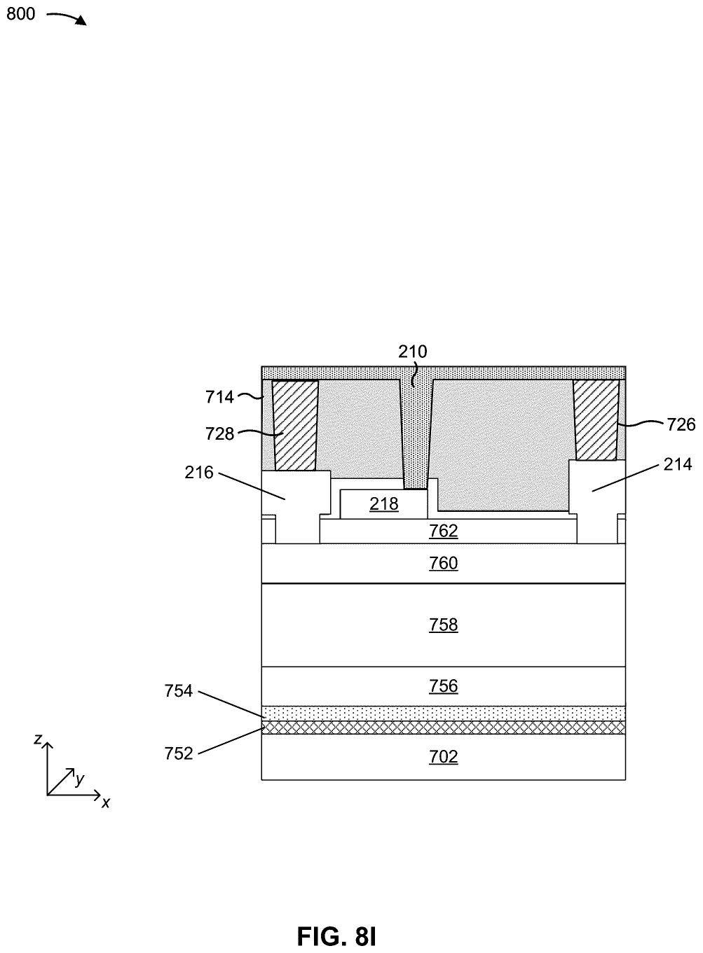

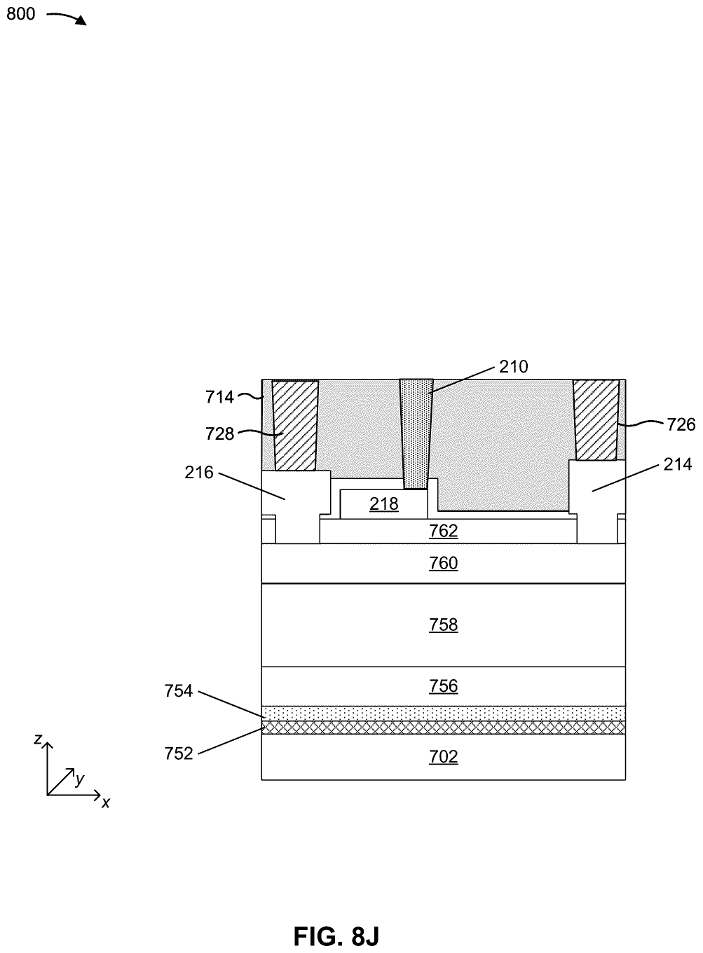

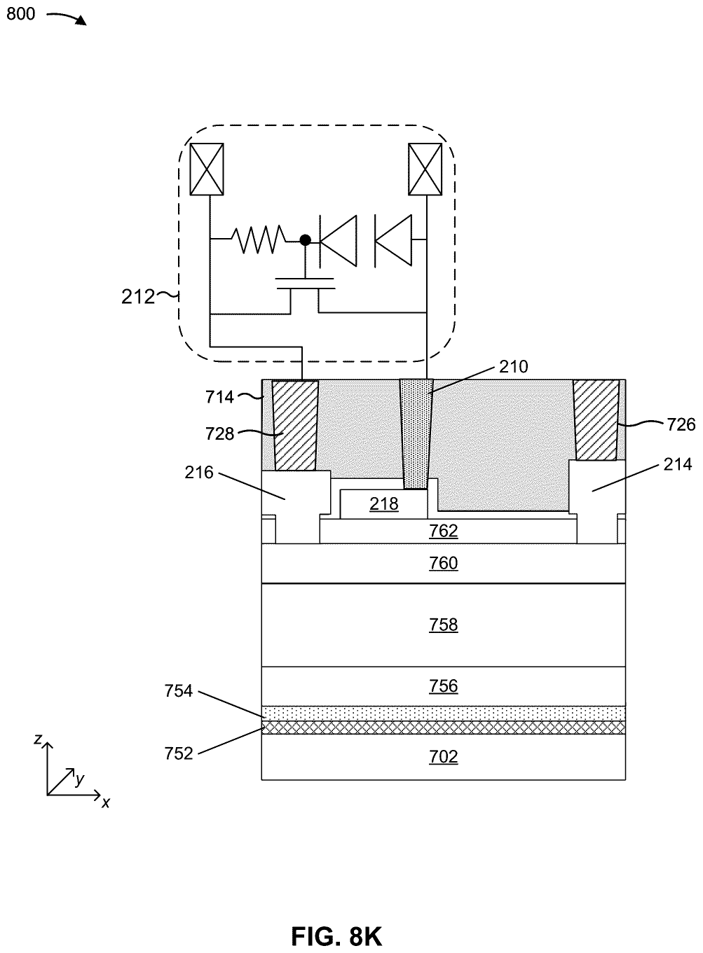

FIGS. 8A-8K are diagrams of an example implementation 800 described herein. Example implementation 800 may be an example process for forming the example semiconductor structure 200 having a resistor over a gate. The semiconductor structure formed using example implementation 800 may be included in a processor, a memory, or another type of electronic device.

As shown in FIG. 8A, the example process for forming the semiconductor structure may be performed in connection with a substrate 702. As described above, the substrate 702 may include a semiconductor die substrate, a semiconductor wafer, a stacked semiconductor wafer, or another type of substrate in which semiconductor pixels may be formed. For example, the substrate 702 may be formed of silicon (Si) (e.g., a silicon substrate), a material including silicon, a III-V compound semiconductor material such as gallium arsenide (GaAs), an SOI, or another type of semiconductor material that is capable of generating a charge from photons of incident light. In some implementations, the substrate 702 is formed of a doped material (e.g., a p-doped material or an n-doped material) such as a doped silicon.

As further shown in FIG. 8A, an adhesive layer 752 may be formed over the substrate 702. For example, a deposition tool 102 may form the adhesive layer 752 over and/or on a frontside surface of the substrate 702. In some implementations, a deposition tool 102 may form the adhesive layer 752 using a spin-coating technique, a CVD technique, a PVD technique, an ALD technique, and/or another deposition technique. The adhesive layer 752 may be planarized after deposition. For example, a planarization tool 110 may perform a CMP process on the adhesive layer 752.

As shown in FIG. 8A, a growth seed layer 754 may be formed over the substrate 702. For example, a deposition tool 102 may form the growth seed layer 754 over and/or on a frontside surface of the substrate 702. In some implementations, the growth seed layer 754 may comprise silicon (Si), such as p-silicon. Accordingly, a deposition tool 102 may form the growth seed layer 754 using epitaxial growth on the substrate 702. A deposition tool 102 may form the growth seed layer 754 using epitaxial growth.

As further shown in FIG. 8A, a seed layer 756 may be formed using the growth seed layer 754. For example, a deposition tool 102 may form the seed layer 756 over and/or on a frontside surface of the substrate 702. In some implementations, the seed layer 756 may comprise aluminum nitride. Accordingly, a deposition tool 102 may form the seed layer 756 using epitaxial growth on the growth seed layer 754.

As shown in FIG. 8B, one or more buffer layers may be formed. In the example implementation 800, a buffer layer 758 is formed over the seed layer 756. A deposition tool 102 may form the buffer layer 758 over and/or on a frontside surface of the substrate 702. In some implementations, the buffer layer 758 may comprise gallium nitride. Accordingly, a deposition tool 102 may form the buffer layer 758 using epitaxial growth on the seed layer 756.

As shown in FIG. 8C, a heterojunction structure (e.g., formed of III-V materials) may be deposited over the buffer layer 758. For example, the heterojunction structure may include a layer 760 formed of a III-V material with a first bandgap (e.g., undoped GaN or UID-GaN) and a layer 762 formed of a III-V material with a second bandgap (e.g., AlGaN). A deposition tool 102 may form the layers 760 and 762 using a spin-coating technique, a CVD technique, a PVD technique, an ALD technique, and/or another deposition technique.

As shown in FIG. 8D, an HEMT process may be performed. For example, a source 216 and a drain 214 may be formed over the heterojunction structure. A deposition tool 102 may form the source 216 and the drain 214 using a spin-coating technique, a CVD technique, a PVD technique, an ALD technique, and/or another deposition technique.

As further shown in FIG. 8D, the HEMT process may further include a gate 218 being formed over the heterojunction structure. A deposition tool 102 may form the gate 218 using a spin-coating technique, a CVD technique, a PVD technique, an ALD technique, and/or another deposition technique.

Additionally, a dielectric layer 714 may be formed over the drain 214, the source 216, and the gate 218. For example, a deposition tool 102 may form the dielectric layer 714 over and/or on the frontside surface of the substrate 702. In some implementations, a deposition tool 102 may form the dielectric layer 714 using a spin-coating technique, a CVD technique, a PVD technique, an ALD technique, and/or another deposition technique.

As shown in FIG. 8E, a recess 802 may be formed over the source 216, and a recess 804 may be formed over the drain 214. For example, an etch tool 108 may form the recess 802 to expose a surface of the source 216 and form the recess 804 to expose a surface of the drain 214. In some implementations, a deposition tool 102 may form a photoresist layer over and/or on the frontside surface of the substrate 702, an exposure tool 104 may expose the photoresist layer to a radiation source to form a pattern on the photoresist layer, and a developer tool 106 may develop and remove portions of the photoresist layer to expose the pattern. Accordingly, an etch tool 108 may etch a portion of the dielectric layer 714 above the drain 214 and the source 216. For example, an etch tool 108 may use a wet etch technique, a dry etch technique, a plasma-enhanced etch technique, and/or another type of etch technique to etch the portion of the dielectric layer 714. A photoresist removal tool 114 may remove the remaining portions of the photoresist layer (e.g., using a chemical stripper, a plasma asher, and/or another technique) after the dielectric layer 714 is etched. Although the example implementation 800 is described with the recesses 802 and 804 being formed during a same etching cycle, other examples may include using one cycle for the recess 802 and another cycle for the recess 804.

As shown in FIG. 8F, a contact 726 may be formed over the drain contact 720, and a contact 728 may be formed over the source contact 722. For example, a deposition tool 102 may form the contacts 726 and 728 in the recesses 804 and 802, respectively. In some implementations, a deposition tool 102 may form the contacts 726 and 728 using a spin-coating technique, a CVD technique, a PVD technique, an ALD technique, and/or another deposition technique. As further shown in FIG. 8D, material of the contacts 726 and 728 may overflow the recesses 802 and 804. Accordingly, as shown in FIG. 8G, a planarization tool 110 removes excess material using CMP. Although the example implementation 800 is described with the contacts 726 and 728 being formed at the same time, other examples may include forming the contact 726 separately from forming the contact 728.

As shown in FIG. 8H, a recess 806 may be formed over the gate 218. For example, an etch tool 108 may form the recess 806 to expose a surface of the gate 218. In some implementations, a deposition tool 102 may form a photoresist layer over and/or on the frontside surface of the substrate 702, an exposure tool 104 may expose the photoresist layer to a radiation source to form a pattern on the photoresist layer, and a developer tool 106 may develop and remove portions of the photoresist layer to expose the pattern. Accordingly, an etch tool 108 may etch a portion of the dielectric layer 714 above the gate 218. For example, an etch tool 108 may use a wet etch technique, a dry etch technique, a plasma-enhanced etch technique, and/or another type of etch technique to etch the portion of the dielectric layer 714. A photoresist removal tool 114 may remove the remaining portions of the photoresist layer (e.g., using a chemical stripper, a plasma asher, and/or another technique) after the dielectric layer 714 is etched. Although the example implementation 800 is described with the recess 806 being formed separately from the recesses 802 and 804, other examples may include forming the recesses 802 and 804 at the same time as the recess 806.

As shown in FIG. 8I, a resistor 210 may be formed over the gate contact 718. For example, a deposition tool 102 may form the resistor 210 in the recess 806. In some implementations, a deposition tool 102 may form the resistor 210 using a spin-coating technique, a CVD technique, a PVD technique, an ALD technique, and/or another deposition technique. The resistor 210 may contact the gate 218 physically, as shown in FIG. 8I. Alternatively, as shown in FIG. 7A, the resistor 210 may contact the gate 218 electrically. In other words, the resistor 210 may be formed in series, electrically, with the gate 218.

When the resistor 210 is a silicon resistor (e.g., an SiCr resistor, an OD resistor, a PO resistor, or a metal gate resistor, among other examples), silicon may be included as a deposited material along with a metal (for an SiCr resistor or a metal gate resistor) or an oxide (for an OD resistor or a PO resistor). When the resistor 210 is a metal nitride resistor (e.g., a TiN resistor), metal may be included as a deposited material along with nitrogen. When the resistor 210 is a GaN resistor (e.g., a 2 DEG resistor), gallium may be included as a deposited material along with nitrogen.

As further shown in FIG. 8I, the material of the resistor 210 may overflow the recess 806. Accordingly, as shown in FIG. 8J, a planarization tool 110 removes excess material using CMP.

As shown in FIG. 8K, a clamp circuit 212 may be formed to electrically connect to the contact 728 and the resistor 210 but not the contact 726 (which may, for example, connect to a ground or another destination separate from the clamp circuit 212). In some implementations, a deposition tool 102 may form additional dielectric layers (optionally with additional ESLs). In some implementations, a deposition tool 102 may form the additional dielectric layers (optionally with the additional ESLs) using a spin-coating technique, a CVD technique, a PVD technique, an ALD technique, and/or another deposition technique. Therefore, circuit components of the clamp circuit 212 may be formed in the additional dielectric layers (e.g., similarly as described above for the drain 214, the source 216, the gate 218, and/or any contacts described herein). In some implementations, all components of the clamp circuit 212 are formed after the resistor 210 is formed. Alternatively, some component of the clamp circuit 212 (e.g., diodes) may be formed in a front end of line (FEOL) with the resistor 210, such that a connection between any components in the FEOL and the resistor 210 are formed after the resistor 210 is formed.

As indicated above, FIGS. 8A-8K are provided as an example. Other examples may differ from what is described with regard to FIGS. 8A-8K. For example, although the example implementation 800 is illustrated using the clamp circuit 212 from FIG. 2, other clamp circuits described herein may be used, such as the clamp circuit from FIG. 4, the clamp circuit from FIG. 5, or the clamp circuit from FIG. 6. Additionally, or alternatively, although the example implementation 800 is shown with reference to the example semiconductor structure 750 of FIG. 7B, processes described in connection with FIGS. 8A-8K may similarly be used to form the resistor 210 in the example semiconductor structure 700 of FIG. 7A. Additionally, or alternatively, although the example implementation 800 is illustrated with forming the clamp circuit 212 over the substrate 702, the clamp circuit 212 may alternatively be formed over a separate substrate and connected to the contact 728 and the resistor 210 via wafer bonding.

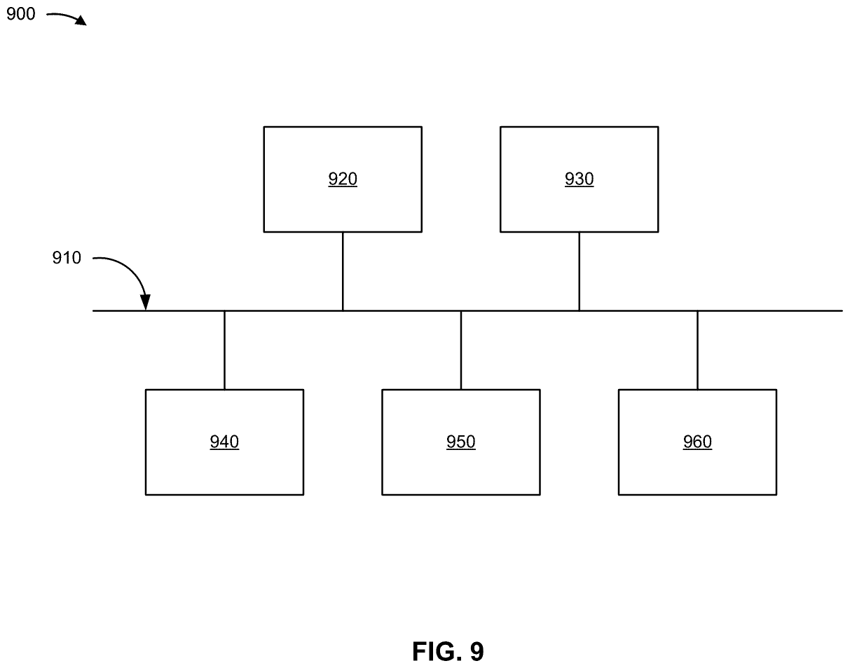

FIG. 9 is a diagram of example components of a device 900 described herein. In some implementations, one or more of the semiconductor processing tools 102-116 and/or the wafer/die transport tool 118 may include one or more devices 900 and/or one or more components of device 900. As shown in FIG. 9, device 900 may include a bus 910, a processor 920, a memory 930, an input component 940, an output component 950, and a communication component 960.

Bus 910 may include one or more components that enable wired and/or wireless communication among the components of device 900. Bus 910 may couple together two or more components of FIG. 9, such as via operative coupling, communicative coupling, electronic coupling, and/or electric coupling. Processor 920 may include a central processing unit, a graphics processing unit, a microprocessor, a controller, a microcontroller, a digital signal processor, a field-programmable gate array, an application-specific integrated circuit, and/or another type of processing component. Processor 920 is implemented in hardware, firmware, or a combination of hardware and software. In some implementations, processor 920 may include one or more processors capable of being programmed to perform one or more operations or processes described elsewhere herein.

Memory 930 may include volatile and/or nonvolatile memory. For example, memory 930 may include random access memory (RAM), read only memory (ROM), a hard disk drive, and/or another type of memory (e.g., a flash memory, a magnetic memory, and/or an optical memory). Memory 930 may include internal memory (e.g., RAM, ROM, or a hard disk drive) and/or removable memory (e.g., removable via a universal serial bus connection). Memory 930 may be a non-transitory computer-readable medium. Memory 930 stores information, instructions, and/or software (e.g., one or more software applications) related to the operation of device 900. In some implementations, memory 930 may include one or more memories that are coupled to one or more processors (e.g., processor 920), such as via bus 910.

Input component 940 enables device 900 to receive input, such as user input and/or sensed input. For example, input component 940 may include a touch screen, a keyboard, a keypad, a mouse, a button, a microphone, a switch, a sensor, a global positioning system sensor, an accelerometer, a gyroscope, and/or an actuator. Output component 950 enables device 900 to provide output, such as via a display, a speaker, and/or a light-emitting diode. Communication component 960 enables device 900 to communicate with other devices via a wired connection and/or a wireless connection. For example, communication component 960 may include a receiver, a transmitter, a transceiver, a modem, a network interface card, and/or an antenna.

Device 900 may perform one or more operations or processes described herein. For example, a non-transitory computer-readable medium (e.g., memory 930) may store a set of instructions (e.g., one or more instructions or code) for execution by processor 920. Processor 920 may execute the set of instructions to perform one or more operations or processes described herein. In some implementations, execution of the set of instructions, by one or more processors 920, causes the one or more processors 920 and/or the device 900 to perform one or more operations or processes described herein. In some implementations, hardwired circuitry is used instead of or in combination with the instructions to perform one or more operations or processes described herein. Additionally, or alternatively, processor 920 may be configured to perform one or more operations or processes described herein. Thus, implementations described herein are not limited to any specific combination of hardware circuitry and software.

The number and arrangement of components shown in FIG. 9 are provided as an example. Device 900 may include additional components, fewer components, different components, or differently arranged components than those shown in FIG. 9. Additionally, or alternatively, a set of components (e.g., one or more components) of device 900 may perform one or more functions described as being performed by another set of components of device 900.

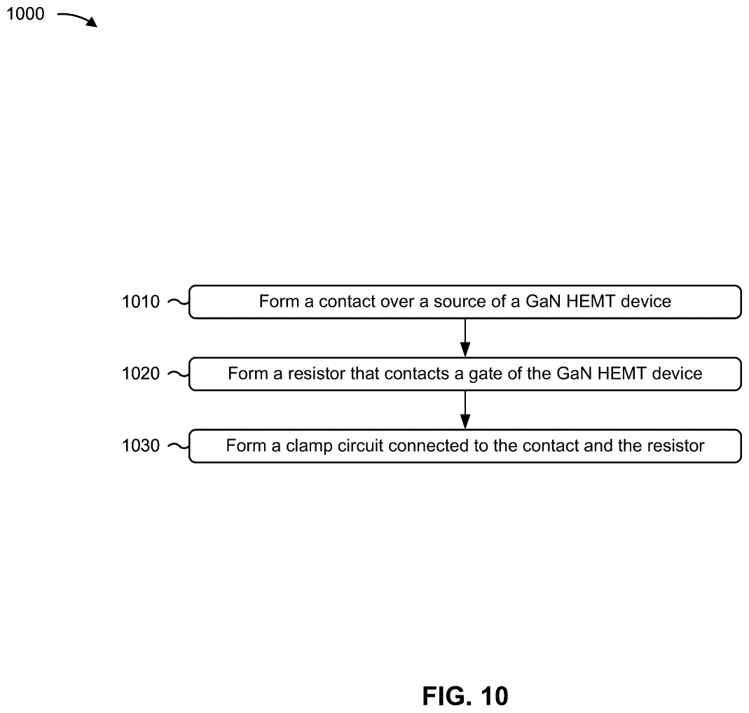

FIG. 10 is a flowchart of an example process 1000 associated with forming a semiconductor device described herein. In some implementations, one or more process blocks of FIG. 10 are performed by one or more semiconductor processing tools (e.g., one or more of the semiconductor processing tools 102-116). Additionally, or alternatively, one or more process blocks of FIG. 10 may be performed by one or more components of device 900, such as processor 920, memory 930, input component 940, output component 950, and/or communication component 960.

As shown in FIG. 10, process 1000 may include forming a contact over a source of a gallium nitride (GaN) high-electron-mobility transistor (HEMT) device (block 1010). For example, one or more of the semiconductor processing tools 102-116 may form a contact 728 over a source 216 of a GaN HEMT device 220, as described herein.

As further shown in FIG. 10, process 1000 may include forming a resistor that contacts a gate of the GaN HEMT device (block 1020). For example, one or more of the semiconductor processing tools 102-116 may form a resistor 210 that contacts a gate 218 of the GaN HEMT device 220, as described herein.

As further shown in FIG. 10, process 1000 may include forming a clamp circuit connected to the contact and the resistor (block 1030). For example, one or more of the semiconductor processing tools 102-116 may form a clamp circuit 212 connected to the contact 728 and the resistor 210, as described herein.

Process 1000 may include additional implementations, such as any single implementation or any combination of implementations described below and/or in connection with one or more other processes described elsewhere herein.

In a first implementation, forming the contact 728 includes forming a recess 802 over the source 216, depositing metal in the recess 802 to form the contact 728, and removing excess metal using CMP.

In a second implementation, process 1000 includes forming an additional contact 726 over a drain 214 of the GaN HEMT device 220, where the additional contact 726 is not connected to the clamp circuit 212.

In a third implementation, forming the resistor 210 includes forming a recess 806 over the gate 218, depositing material in the recess 806 to form the resistor 210, and removing excess material using CMP.

In a fourth implementation, process 1000 includes connecting an IO of the clamp circuit 212 to a control device 202.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, providing a resistor between a gate of a target device (e.g., a GaN HEMT device) and a clamp circuit improves ESD protection between an IO and the target device. For example, the resistor may result in ESD protection between the IO and a source of the target device and between the IO and a drain of the target device may be at least 2 kv under the HBM. Because ESD protection is improved, chances of burn out in the target device are reduced. Additionally, larger currents may be applied in the clamp circuit without risk of ESD.

As described in greater detail above, some implementations described herein provide a semiconductor structure. The semiconductor structure includes a source and a drain in a substrate. The semiconductor structure includes a gate of a gallium nitride (GaN) high-electron-mobility transistor (HEMT) device configured to control a channel between the source and the drain. The semiconductor structure includes a resistor between the gate and a circuit on the substrate.

As described in greater detail above, some implementations described herein provide a method. The method includes forming a contact over a source of a gallium nitride (GaN) high-electron-mobility transistor (HEMT) device. The method includes forming a resistor that contacts a gate of the GaN HEMT device. The method includes forming a clamp circuit connected to the contact and the resistor.

As described in greater detail above, some implementations described herein provide a semiconductor device. The semiconductor device includes a source and a drain in a substrate. The semiconductor device includes a gate configured to control a channel between the source and the drain. The semiconductor device includes a clamp circuit on the substrate and configured to perform electrostatic discharge (ESD). The semiconductor device includes a resistor between the gate and the clamp circuit.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a source and a drain in a substrate;
a gate of a gallium nitride (GaN) high-electron-mobility transistor (HEMT) device configured to control a channel between the source and the drain; and
a resistor between the gate and a circuit on the substrate.

2. The semiconductor structure of claim 1, wherein the resistor comprises a silicon resistor.

3. The semiconductor structure of claim 1, wherein the resistor comprises a metal nitride resistor.

4. The semiconductor structure of claim 1, wherein the resistor comprises a GaN resistor.

5. The semiconductor structure of claim 1, wherein the resistor results in an electrostatic discharge protection, under a human body model, of at least 2 kilovolts between an input/output (IO) and the source and between the IO and the drain.

6. A method, comprising:
forming a contact over a source of a gallium nitride (GaN) high-electron-mobility transistor (HEMT) device;
forming a resistor that contacts a gate of the GaN HEMT device; and
forming a clamp circuit connected to the contact and the resistor.

7. The method of claim 6, wherein forming the contact comprises:
forming a recess over the source;
depositing metal in the recess to form the contact; and
removing excess metal using chemical mechanical planarization.

8. The method of claim 6, further comprising:
forming an additional contact over a drain of the GaN HEMT device,
wherein the additional contact is not connected to the clamp circuit.

9. The method of claim 6, wherein forming the resistor comprises:
forming a recess over the gate;
depositing material in the recess to form the resistor; and
removing excess material using chemical mechanical planarization.

10. The method of claim 6, further comprising:
connecting an input/output of the clamp circuit to a control device.

11. A semiconductor device, comprising:
a source and a drain in a substrate;
a gate configured to control a channel between the source and the drain;
a clamp circuit on the substrate and configured to perform electrostatic discharge (ESD); and
a resistor between the gate and the clamp circuit.

12. The semiconductor device of claim 11, wherein the clamp circuit comprises a static clamp.

13. The semiconductor device of claim 11, wherein the clamp circuit comprises a series of diodes configured to control a field-effect transistor.

14. The semiconductor device of claim 11, wherein the clamp circuit comprises a capacitor-resistor clamp.

15. The semiconductor device of claim 11, wherein the clamp circuit comprises a resistor-capacitor clamp.

16. The semiconductor device of claim 11, wherein the clamp circuit comprises a capacitor and a resistor configured to control a field-effect transistor.

17. The semiconductor device of claim 11, wherein the clamp circuit comprises an inverter configured to control a field-effect transistor.

18. The semiconductor device of claim 11, wherein the clamp circuit comprises a forward diode connected to a field-effect transistor.

19. The semiconductor device of claim 11, wherein the clamp circuit is configured to perform the ESD based on a voltage threshold.

20. The semiconductor device of claim 11, wherein the clamp circuit is configured to perform the ESD based on a time constant.
